(19) United States
(12) Patent Application Publication
(10) Pub. No.: US 2026/0088248 A1
(43) Pub. Date: Mar. 26, 2026

(54) METHOD AND SYSTEM FOR CALIBRATING A CHARGED-PARTICLE SPECTROMETER

(71) Applicants: CENTRE NATIONAL DE LA RECHERCHE SCIENTIFIQUE, PARIS (FR); UNIVERSITE PARIS-SACLAY, GIF-SUR-YVETTE (FR)

(72) Inventors: Luiz GALVAO TIZEI, BOURG-LA-REINE (FR); Yves AUAD, PARIS (FR); Jean-Denis BLAZIT, FORGES-LES-BAINS (FR); Marcel TENCE, ISSY-LES-MOULINEAUX (FR); Mathieu KOCIAK, PALAISEAU (FR)

(73) Assignees: CENTRE NATIONAL DE LA RECHERCHE SCIENTIFIQUE, PARIS (FR); UNIVERSITE PARIS-SACLAY, GIF-SUR-YVETTE (FR)

(21) Appl. No.: 19/106,716

(22) PCT Filed: Jul. 27, 2023
(86) PCT No.: PCT/EP2023/070827

§ 371 Date: Feb. 26, 2025

(30) Foreign Application Priority Data
Aug. 31, 2022 (EP) 22306288.6

(51) Int. Cl. H01J 37/22; H01J 37/244

(52) U.S. Cl. CPC H01J 37/228; H01J 37/244; H01J 2237/24485; H01J 2237/30438

(57) ABSTRACT

A method for calibrating a charged-particle spectrometer including generating a monochromatic incident charged-particle beam having a first energy; generating an incident laser beam having a second energy; illuminating a surface with the laser beam to generate an evanescent electromagnetic field in a region near the surface; spatially and temporally superimposing the laser beam and the incident charged-particle beam in the region to couple them via the evanescent electromagnetic field by generating a charged-particle beam as an output beam with a spectrum having distinct peaks of energies that are spectrally separated by a value equal to the second energy; measuring, by the spectrometer, all or part of the spectrum of the output beam, then determining a variation in energy of at least two of the distinct energy peaks with respect to the first energy; and determining a value of the scale factor S and a value of the offset.

### TECHNICAL FIELD

The present invention relates to the field of charged-particle spectrometers, and more particularly to the calibration of charged-particle spectrometers. “Charged-particle spectrometers” are spectrometers designed to measure the energy spectrum of charged molecules, electrons or ions.

### PRIOR ART

FIG. 1A shows a typical electron energy loss spectrum (or EELS) in the case where an interaction occurs between the electron and light. The central, zero-energy peak is known as the Zero Loss Peak (ZLP). Two peaks can be seen on either side, respectively the first-order stimulated EELS peak (right) and the stimulated electron energy gain spectrum (EEGS) peak (left).

As is well known, measurements made by charged particle spectrometers, and more particularly electron spectrometers, suffer from several types of calibration errors.

FIG. 1B shows the effect of a linear spectrometer calibration error on the measurement of the electron energy spectrum with the spectrum shown in FIG. 1A. By way of example, FIG. 1B shows that the peaks are shifted symmetrically with respect to 0 towards energies that are greater in absolute value than those observed in FIG. 1A. More generally, the effect of a scale error.

FIG. 1C shows the effect of a spectrometer offset type error on the measurement of the electron energy spectrum with the spectrum shown in FIG. 1A. Here, we observe that the peaks are shifted non-symmetrically by the same value O towards higher energies than those observed in FIG. 1A. More generally, the effect of an offset error is the addition of a value equal to the offset O to the energy value of the EEGS and EELS peaks; this value O can be negative.

FIG. 1D shows the effect of a non-linear spectrometer error on the measurement of the electron energy spectrum with the spectrum shown in FIG. 1A. It can be seen that the peaks are shifted non-symmetrically with respect to 0 and differently between the EEGS and EELS peak with respect to FIG. 1A.

In the best electron spectrometers, typically used in electron microscopes for EELS spectroscopy, linear precision and accuracy are limited to around 1% (10 eV to 1000 eV or 20 meV to 2 eV). “Linear precision and accuracy” here refers to the precision of the determination of S and O, respectively. In fact, there are typically two known ways of calibrating the scale factor S and offset O of charged particle spectra.

A first method consists in using a standard through which the charged particle beam passes and which has a spectral characteristic (absorption, gain) at a known energy. This spectral characteristic can be determined by prior calculation or experiment. It is then possible to determine the scale factor S and the offset O by measuring the spectrum of the charged particles without crossing the standard and by measuring the spectrum of the charged particles with crossing the standard. However, this method has one major drawback. Indeed, the uncertainties related to the transition energy in solids lead to uncertainty in the determination of the scale factor S and the offset O. For example, the absorption threshold L of Ni in NiO can be determined with a precision of 0.1 eV, but with low accuracy because the energy position of the precise threshold L depends on the actual oxidation state of Ni.

A second method consists in modifying the energy of the emitted beam particle by an assumed known amount, typically by applying a magnetic field or an electric potential. It is then possible to determine the scale factor S and the offset O by two measurements of the charged particle spectrum with two different energies.

However, at present, both methods suffer from uncertainties due to deviations in the electron trajectory caused by various effects (leakage fields in the optical elements of charged particles, aberrations, etc.). These effects lead to uncertainty in determining the scale factor S and the offset O.

The invention aims to overcome certain problems of the prior art. To this end, an object of the invention is a method (and an associated system) for calibrating a charged particle spectrometer, comprising a step consisting in effecting coupling, via an evanescent electromagnetic field, between a laser beam and a charged particle beam. This coupling generates a beam of charged particles with a spectrum comprising a plurality of distinct energy peaks separated spectrally by an energy equal to the energy of the laser beam. Using the charged-particle spectrometer, a variation in the energy of at least two of the distinct energy peaks is determined in relation to the energy of the charged particle beam. From the energy variations, it is then possible to determine a value for the scale factor S and an offset value O specific to the spectrometer's measurement of the output beam spectrum.

The method of the invention has the advantage of enabling the scale factor S and offset O to be determined with a precision limited only by the precision of the laser beam energy. It offers several orders of magnitude improvement in measuring the scale factor S and offset 0 with respect to other methods known in the art.

### SUMMARY OF THE INVENTION

To this end, an object of the invention is a method for calibrating a charged-particle spectrometer, comprising the following steps:
A. generating a monochromatic incident charged particle beam having a first energy E₁;
B. generating an incident laser beam having a second energy E₂;
C. illuminating a surface of a sample with the incident laser beam to generate an evanescent electromagnetic field in a region in the vicinity of said surface;
D. spatially and temporally superimposing the incident laser beam and the incident charged particle beam in said region in order to couple them via said evanescent electromagnetic field, generating a charged particle beam known as an output beam having a spectrum comprising a plurality of distinct energy peaks spectrally separated by a value equal to the second energy E₂;
E. using the spectrometer, measuring all or part of the spectrum of the output beam, then determining a variation in energy ΔE of at least two of the distinct energy peaks with respect to the first energy E₁;
F. determining a value of the scale factor S and a value of the offset O specific to said measurement of the spectrum of the output beam by the spectrometer from the energy variations ΔE.

Preferentially, the variation in energy ΔE of each of the at least two distinct energy peaks is equal to ΔE=±p×E₂, with p a positive or zero integer equal to a number of inter-peak intervals separating said distinct energy peak from the peak of the spectrum at the first energy E₁ and wherein said variation in energy ΔE of each of the at least two distinct energy peaks is determined in step E by the spectrometer by the following relation, referred to as the first equation:

$$Δ E ( c ) = c \times S + O + NL ( c )$$

with c a channel of a matrix detector of the spectrometer where said distinct energy peak is detected, with NL(c) a function of the channel c representative of non-linearities undergone by the charged particles during their path and detection, a so-called NL function.

According to a first embodiment, it is determined that said non-linearities undergone by the charged particles are weak or zero, and, in step E, the variation in energy ΔE of two of the distinct energy peaks, numbered by the index 1 and 2 respectively via the first equation is determined so as to obtain the following first system (S1):

$$\{ \begin{matrix}Δ E ( {c}_{1} ) = {c}_{1} \times S + O = \pm {n}_{1} \times {E}_{2} \\ Δ E ( {c}_{2} ) = {c}_{2} \times S + O = \pm {n}_{2} \times {E}_{2}\end{matrix} \qquad ( S 1 )$$

step F consisting in solving the first equation system (S1) to determine the value of the scale factor S and the value of the offset.

Preferentially, in the first embodiment, an integer m>1 of inter-peak intervals separating said two peaks for which the variation in energy ΔE is determined is such that an error on the determination of the scale factor value is less than or equal to 1% of the second energy.

According to a second embodiment, it is determined that the non-linearities undergone by said charged particles are not weak or zero and, in step E, the variation in energy ΔE of a number N>2 of distinct energy peaks each numbered by an index i∈[1; N] is determined via the first equation so as to obtain the following second system (S2):

$$i ∈ [ 1 ; N ] \{ Δ E ( {c}_{i} ) = {c}_{i} \times S + O + NL ( {c}_{i} ) = \pm {n}_{i} \times {E}_{2}$$

step F consisting in:
   solving the second equation system (S2) to determine the value of the scale factor S and the value of the offset 0 and the N values NL(cᵢ), i∈[1; N] of the NL function;
   extrapolating the NL function from the N values NL(cᵢ), i∈[1; M] to characterize the non-linearities undergone by the charged particles during their path and detection.

Preferentially, the method of the second embodiment comprises a step subsequent to step F consisting in iteratively minimizing the values of the NL function by repeating steps A to F a plurality of times and modifying parameters of the path and detection of charged particles between each iteration.

According to one embodiment, step D further comprises a sub-step consisting in measuring a spectrum of the incident laser beam simultaneously with the generation of the output beam, the determination of the value of the scale factor S and the value of the offset O being performed from said measurement of the spectrum of the incident laser beam.

Another object of the invention is a system for calibrating a charged-particle spectrometer, said system comprising:
a charged particle source adapted to generate a monochromatic incident charged particle beam having a first energy E₁;
a laser source adapted to generate an incident laser beam having a second energy E₂;
an optical and charged particle transport assembly adapted for:
illuminating a surface of a sample with the incident laser beam to generate an evanescent electromagnetic field in a region in the vicinity of said surface;
spatially and temporally superimposing the incident laser beam and the incident charged particle beam in said region in order to couple them via said evanescent electromagnetic field so as to generate a charged particle beam known as an output beam having a spectrum comprising a plurality of distinct energy peaks spectrally separated by a value equal to the second energy E₂;
said spectrometer being adapted to measure all or part of the spectrum of the output beam, said system further comprising a processor connected to the spectrometer and adapted for:
determining a variation in energy ΔE of at least two of the distinct energy peaks with respect to the first energy E₁;
determining a value of the scale factor S and a value of the offset O specific to said measurement of the spectrum of the output beam by the spectrometer from the energy variations ΔE.

Preferentially, the incident laser beam is a continuous beam or a pulsed beam with a spectral width of less than 40 meV.

According to one embodiment, the system comprises an additional optical spectrometer adapted to measure a spectrum of the incident laser beam simultaneously with the generation of the output beam, the processor also being connected to the additional spectrometer so that the determination of the value of the scale factor S and the value of the offset O is effected from said measurement of the spectrum of the incident laser beam.

Preferentially, the laser source and the transport assembly are adapted so that the incident laser beam has an intensity greater than or equal to 10⁸ W/cm² in said region.

Preferentially, the laser source and transport assembly are adapted so that the incident laser beam is polarized in a direction adapted to the geometry and the symmetry of the sample in order to locally maximize the intensity of the evanescent field in said region.

Preferentially, said transport assembly comprises an off-axis parabola adapted to focus the incident laser beam onto said surface of the sample, said parabola having an aperture through which the incident charged particle beam passes so that it co-propagates with the incident laser beam towards said region after the latter has reflected off said off-axis parabola.

Preferentially, the system comprises a resonant optical cavity for the incident laser beam wherein the sample is arranged, said transport assembly and said optical cavity being further adapted so that the incident laser beam makes a plurality of reflections in the optical cavity as it passes through said region.

### BRIEF DESCRIPTION OF THE FIGURES

Further features, details and advantages of the invention will become apparent upon reading the description made with reference to the appended drawings given by way of example and which show, respectively:

FIG. 1A, a typical electron energy loss spectrum (EELS) where an interaction occurs between the electron and light

FIG. 1B, FIG. 1C, FIG. 1D, the effect of a scaling error, an offset-type error and a non-linear error, respectively, on the measurement of the electron energy spectrum with the spectrum in FIG. 1A,

FIG. 2, a representation of the method of the invention for calibrating a charged-particle spectrometer,

FIG. 3, a schematic representation of the system of the invention for calibrating a charged-particle spectrometer,

FIG. 4A, a representation of the evanescent field strength generated in the region,

FIG. 4B, an energy diagram representing the charged particle-photon interaction of step D of the method of the invention,

FIG. 4C, an example of an energy loss spectrum with three EELS peaks, three EEGS peaks and the ZLP peak,

FIG. 5, a schematic representation of a particular embodiment of the invention wherein the system of the invention comprises an additional optical spectrometer adapted to measure a spectrum of the incident laser beam simultaneously with the generation of the output beam,

FIG. 6, a schematic representation of a particular embodiment of the invention, wherein the system of the invention comprises an optical cavity where the sample is arranged,

FIG. 7, a representation of the method according to the second embodiment of the invention,

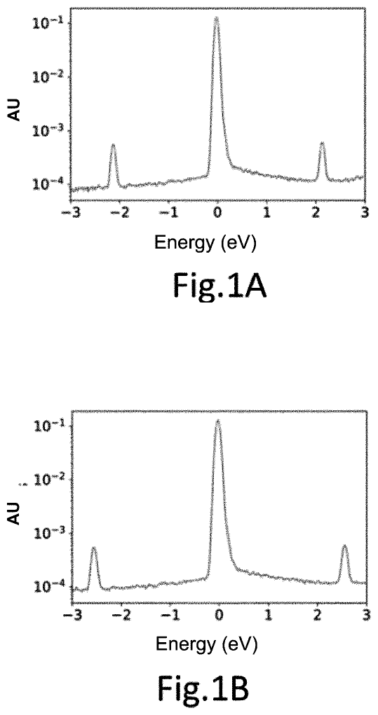

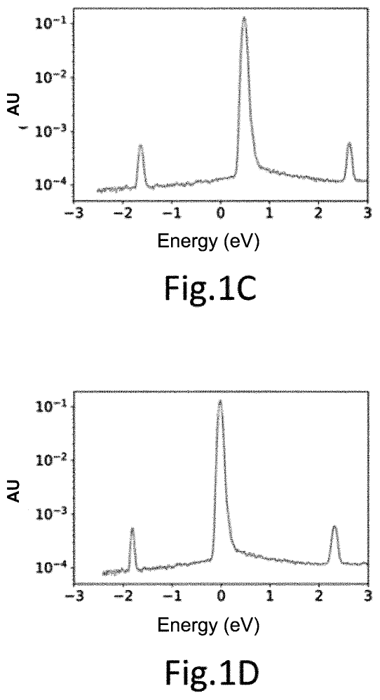

In the figures, unless otherwise indicated, elements are not to scale.

### DETAILED DESCRIPTION

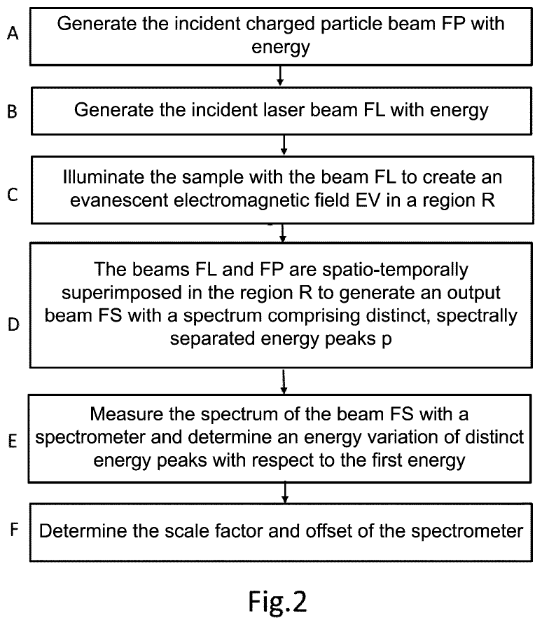

FIG. 2 is a representation of the method of the invention for calibrating a charged-particle spectrometer SM. As mentioned above, the method of the invention aims to calculate the scale factor S and the offset 0 associated with spectrometer SM measurements.

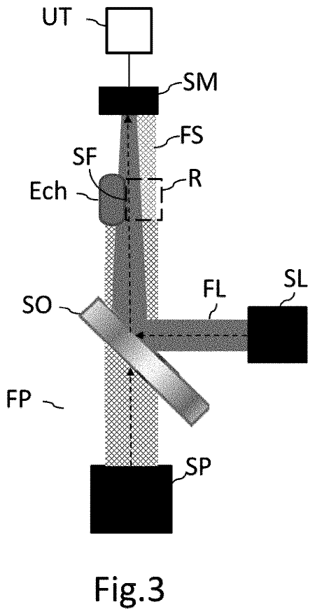

FIG. 3 schematically shows the system 1 according to the invention for calibrating a charged-particle spectrometer SM. The system 1 is specifically adapted to implement the method of the invention shown in FIG. 2. The system 1 in particular comprises a charged particle source SP, a laser source SL, an optical and charged particle transport assembly SO, a sample Ech and the spectrometer SM.

In a step A of the method of the invention, the charged particle source SP generates an incident charged particle beam FP. The source SP is adapted so that the beam FP is monochromatic and has a first energy E₁. “Monochromatic” here means that the beam FP has the first energy E₁ à<±0.1%

In a step B, the laser source SL generates an incident laser beam FL with a second energy E₂=ℏω₂, where ω₂ is the center frequency of the incident laser beam. According to one embodiment, the laser source SL delivers a pulsed beam. Alternatively, in another embodiment, the laser source SL delivers a continuous beam. As will be explained later, the pulse duration—via spectral width—has a direct influence on the accuracy of scale factor S and offset O determination.

The sources SL and SP are configured so that the beams FL and FP are directed towards the transport assembly SO.

In a step C, the transport assembly SO directs the incident laser beam FL so that it illuminates a surface SF of the sample Ech so as to generate an evanescent electromagnetic field EV in a region R close to the surface SF.

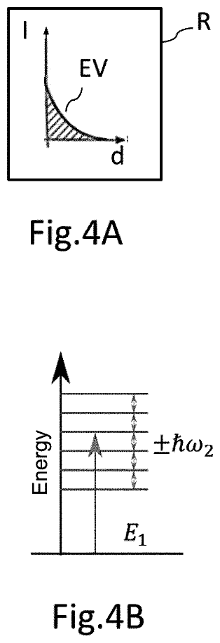

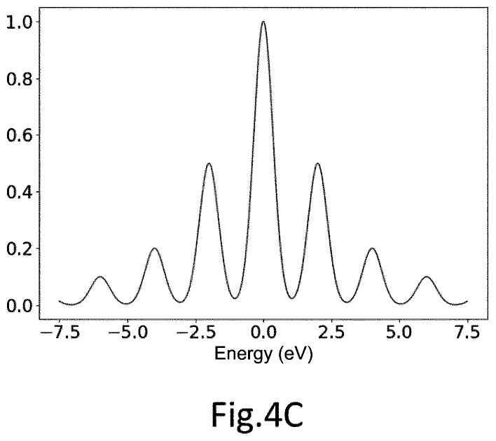

For illustrative purposes only, FIG. 4A shows a representation of the evanescent field strength EV in region R based on the distance d from the surface SF.

The sample of the invention can take any form known to a person skilled in the art enabling the generation of the evanescent field EV by laser illumination. By way of non-limiting example, the sample is a metal surface, a metal nanotube, a metal nanowire, a nanosphere, an optical fiber, a ring-fiber cavity, a waveguide or, more generally, an optical cavity.

In a step D, the transport assembly SO spatially and temporally superimposes the incident laser beam FL and the incident charged particle beam FP in the region R. This superposition enables coupling between the beams FL and FP via the evanescent field EV. This coupling consists in the absorption or emission, by the charged particles, of photons from the laser beam FL and enables the generation of a charged particle beam (called the output beam FS) presenting a spectrum comprising a plurality of distinct energy peaks separated spectrally by a value equal to the second energy E₂.

This coupling mechanism is known to those skilled in the art and is described for photon/electron interaction in Barwick, B., Flannigan, D. J., & Zewail, A. H. (2009). Photon-induced near-field electron microscopy. Nature, 462 (7275), 902-906. This phenomenon is a non-linear mechanism in which a charged particle of the beam FP of initial energy E₁ absorbs or emits n≥1 photons so as to gain or lose an energy equal to a multiple of the energy E₂ of a photon in the laser beam FL. After this interaction, the energy of the charged particle is therefore E₁′=E₁±n×E₂ with E₁′ the energy of the charged particle in the output beam FS. FIG. 4B shows the energy diagram representing this interaction.

As a result of this photon/charged particle interaction, the output beam FS therefore has an energy spectrum comprising a plurality of distinct energy peaks at energies E₁′=E₁±n×E₂ (n≥1) and at an energy E₁ (the so-called ZLP peak). In the following, for ease of notation, the output beam FS will be said to have an energy spectrum comprising a plurality of distinct energy peaks at energies E₁′=E₁±p×E₂ (p integer greater than or equal to 0).

In step E, the output beam is directed into the spectrometer SM, which measures all or part of the spectrum of the output beam FS. More precisely, the spectrometer measures an energy loss spectrum of the output beam FS. In the invention, it is essential that the measured part of the output beam FS spectrum includes at least two of the distinct energy peaks in order to be able to determine the scale factor S and the offset O (see below).

FIG. 4C shows an example of the energy loss spectrum obtained in step E, comprising three EELS peaks and three EEGS peaks and the ZLP peak at zero energy variation (that is, the peak corresponding to charged particles of energy E₁). As a non-limiting example, in FIG. 4C, the laser source SL emits a beam FL with a wavelength of 519 nm, that is, 2.4 eV. Thus, the peaks in the spectrum in FIG. 4C are separated by 2.4 eV. Note that the number p of photons absorbed/emitted by the charged particle of energy E₁′=E₁±p×E₂ is equal to the number of inter-peak intervals separating the distinct energy peak from the ZLP peak.

The system further comprises a processor UT connected to the spectrometer SM and adapted to determine an energy variation ΔE of at least two of the distinct energy peaks relative to the first energy E₁. That is, the processor selects at least two peaks from the measured spectrum, each at an energy E₁′=E₁±p×E₂, then calculates ΔE=E₁′−E₁=±p×E₂. The peaks selected for calculating the energy variation ΔE are not necessarily different from the spectrum peak at energy E₁. The processor can therefore select the ZLP peak and a peak with a specific energy E₁′=E₁±n×E₂ (n≥1).

We note m the number of inter-peak intervals separating the two selected peaks, and note Em the energy separating them.

In a final step F, the processor determines the value of the scale factor S and the offset value O specific to the spectrometer SM from these energy variations ΔE. In fact, as is well known, energy variations ΔE are determined in step E by the spectrometer and processor via the following relationship, referred to as the first equation:

$$Δ E ( c ) = c \times S + O + NL ( c )$$

with c a channel of a matrix detector of the spectrometer where the distinct energy peak is detected, with NL(c) a function of the channel c representative of non-linearities undergone by the charged particles during their path and detection, a so-called NL function. These non-linearities are typically due to the optical components of the system 1 and the matrix detector of the spectrometer.

The term “spectrometer matrix detector channel” is used here to refer to the pixel row or sub-row (or column or sub-column, depending on detector orientation) where the distinct energy peak is detected.

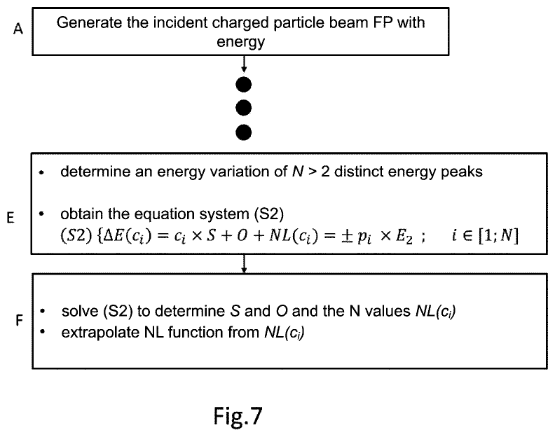

The invention comprises two distinct embodiments, a first embodiment where only the value of the scale factor S and the offset value O (linear error) are determined, and a second embodiment where the value of the scale factor S and the offset value O are determined and the NL function (the non-linear error) is extrapolated (see FIG. 7 and associated description below).

According to the first embodiment of the invention, the processor determines that the non-linearities experienced by the charged particles as they travel and are detected are low or zero. For example, the processor determines that the values c×S+O are much higher than the values NL(c). “Much higher” means that the values c×S+O are more than ten times the values NL(c). In the first embodiment, step E consists in determining the energy variation ΔE of two of the distinct energy peaks, numbered by index 1 and 2, respectively, via the first equation so as to obtain the following first system (S1):

$$\{ \begin{matrix}Δ E ( {c}_{1} ) = {c}_{1} \times S + O = \pm {p}_{1} \times {E}_{2} \\ Δ E ( {c}_{2} ) = {c}_{2} \times S + O = \pm {p}_{2} \times {E}_{2}\end{matrix} \qquad ( S 1 )$$

with c₁ and c₂ the matrix detector channels where the distinct energy peaks of index 1 and 2, respectively, are detected and with p₁ and p₂ the number of photons absorbed/emitted by the charged particles of index peaks 1 and 2, respectively.

We then have a first system (S1) of two equations with two unknowns. Step F of the first embodiment then consists in solving the first equation system (S1) to determine the value of the scale factor S and the value of the offset O.

Let us consider two distinct energy peaks separated by a number of inter-peak intervals equal to m and separated by an energy Eₘ. Let d be the number of channels separating two adjacent distinct energy peaks on the spectrometer matrix detector. “Adjacent distinct energy peaks” means energy peaks separated by an energy equal to E₂. The two selected peaks are separated by a number of channels m×d on the matrix detector.

We then have:

$$S = \frac{{E}_{m}}{m \times d} = \frac{m \times {E}_{2}}{m \times d} = \frac{{E}_{2}}{d} .$$

Let ΔEₘ be the precision of the energy value Eₘ separating the two distinct energy peaks and let Δdₘ be the accuracy of determining the number of channels separating the two distinct energy peaks on the matrix detector. The accuracy ΔEₘ is equal to the precision of the photon energy of the laser beam FL emitted by the source SL. This precision is the spectral width LS of the laser beam FL

In addition, we consider that precision Δdₘ is equal to the detector pixel pitch Δd.

The determination precision of S is then:

$$Δ S = \sqrt{{( \frac{δ S}{δ {E}_{2}} )}^{2} {LS}^{2} + {( \frac{δ S}{δ d} )}^{2} Δ {d}^{2}} = \sqrt{\frac{1}{{d}^{2}} {LS}^{2} + \frac{{E}_{2}^{2}}{{d}^{4}} Δ {d}^{2}}$$

Defining ΔSₘ=ΔS/m, we have:

$$Δ {S}_{m} = \frac{1}{m} \sqrt{\frac{1}{{d}^{2}} Δ {E}_{m}^{2} + \frac{{E}_{2}^{2}}{{d}^{4}} Δ {d}_{m}^{2}}$$

It is observed that the value of the precision on the determination of S is inversely proportional to the number of inter-peak intervals m and is equal to ΔSₘ=ΔS/m as ΔEₘ=LS and as Δdₘ=Δd.

Two important conclusions can be drawn from these calculations:
A. the method of the invention according to the first embodiment of the invention allows a determination of the value of the scale factor S and the offset value O with an error limited by the spectral width LS of the laser beam,
B. in order to improve precision in determining S, it is necessary to measure peaks with a larger number of inter-peak intervals m.

The calibration method of the invention makes it possible to determine a value for the scale factor S with an accuracy ΔS of the order of 0.01% or less of the energy E₂ of the laser beam FL, even when measuring the energy variation ΔE with two distinct energy peaks having a number of inter-peak intervals m equal to 1. For example, with commercial lasers and optical spectrometers, an accuracy of ΔS of 30 μeV for an energy E₂=2 eV (that is, 620 nm wavelength) is achievable using a laser source SL with a spectral width of 10 pm. An improved precision ΔS can be achieved by using a laser with better spectral resolution. At present, even a precision of 0.001% of the energy E₂ for the scale factor S and for the offset O is already two orders of magnitude higher than the spectral resolution of state-of-the-art electronic spectrometers.

According to a preferred embodiment of the invention, the incident laser beam is a continuous beam or a pulsed beam with a spectral width of less than 40 meV. Thus, by adapting the detection of the spectrometer SM, it is possible to determine the value of the scale factor S with an accuracy ΔS less than or equal to 0.01% of the energy E₂.

In one embodiment, the laser source SL is a femtosecond laser with a spectral width of LS=40 meV and the matrix detector of the spectrometer SM has 1000 channels and a dispersion of 20 meV/channel. By measuring the energy variation ΔE with two distinct energy peaks with a number of inter-peak intervals m equal to 5, the value of the scale factor S is determined with an accuracy of

$$Δ S = \frac{20}{m \cdot d} = 0.004 m eV ,$$

or an accuracy ΔS equal to 0.01% of the energy E₂.

More generally, according to a preferred embodiment of the invention, for a fixed spectral width LS, the spectrometer SM is adapted so that the number of inter-peak intervals m separating the two peaks for which the energy variation ΔE is determined is such that ΔS is less than or equal to 1% of the second energy E₂, preferentially less than 0.01% of the second energy E₂.

It has been shown that the probability of the photon/charged particle interaction giving rise to the distinct energy peaks is proportional to the strength of the evanescent field EV (F. Javier Garcia de Abajo et al., Nano Letters, 10, 1859 (2010)). In addition, in a known manner, the detection sensitivity of the spectrometer SM is limited by the background noise generated by a number of factors. Thus, according to a preferred embodiment of the invention, the laser source SL and the transport assembly SO are adapted so that the incident laser beam has an intensity greater than or equal to 10⁸ W/cm² in the region R. This intensity makes it possible to generate an evanescent field EV with an intensity sufficiently high for the rate of photon/charged particle interaction to be sufficiently high to generate a plurality of energy peaks in the output beam FS sufficiently intense to enable their detection by the spectrometer SM. Increasing the intensity of the incident laser beam in the R region will therefore enable the detection of a greater number of distinct peaks in the spectrum of the output beam, thus improving the accuracy of the scaling factor determination S and offset 0 by selecting a number of inter-peak intervals m in step E.

In the embodiment shown in FIG. 3, the transport assembly SO comprises an off-axis parabola allowing focusing of the incident laser beam FL in the region R. The parabola has an aperture through which the incident charged particle beam passes so that it co-propagates with the incident laser beam towards the region after the latter has reflected off the off-axis parabola. This embodiment has the advantage of being simpler to implement.

Although this arrangement is preferred, it is understood that other transport devices for the beams FL and FP may be used by those skilled in the art to form the transport assembly SO. Thus, according to another embodiment, the transport assembly SO comprises one or more mirrors and/or one or more lenses and/or a fiber coupling.

In order to more easily control the temporal superposition of the beams FL and FP, according to one embodiment of the invention, the system 1 comprises a delay line arranged in the optical path of the laser beam FL.

Preferentially, the laser source and transport assembly are adapted so that the incident laser beam is polarized in a direction substantially adapted to the geometry and symmetry of the sample, in order to locally maximize the evanescent field EV intensity in the region R. For example, when the sample is a nanotube or nanowire, polarization in a direction substantially parallel to the longitudinal axis of the nanotube or nanowire maximizes the intensity of the evanescent field EV in the region R.

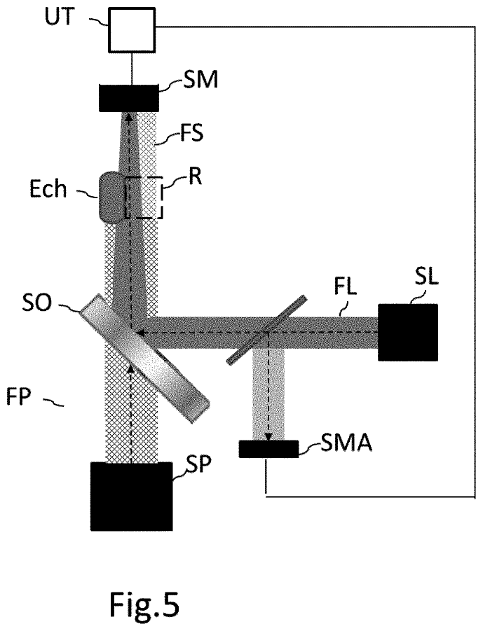

FIG. 5 shows a schematic depiction of a particular embodiment of the invention wherein the system 1 comprises an additional optical spectrometer SMA adapted to measure a spectrum of the incident laser beam simultaneously with the generation of the output beam. In this way, the additional optical spectrometer SMA can measure in real time—or at a predetermined frequency—the second energy E₂(t) and the spectral width LS of the beam FL. Additionally, the processor UT is connected to the additional optical spectrometer SMA, so that the value of the scale factor S and the offset value O is determined from the measurement of the second energy E₂(t) measured by the additional optical spectrometer SMA. This embodiment reduces inaccuracies in the value of the scale factor S and the offset value O due to fluctuations in the value of the second energy over time. It also allows more precise determination of the value of the precision ΔS by measuring the spectral width LS.

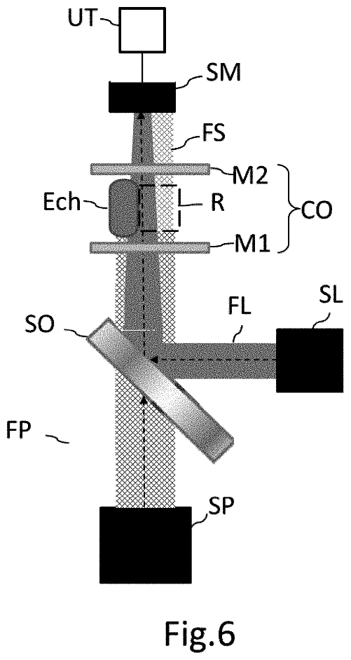

FIG. 6 shows a particular embodiment of the invention wherein the system 1 comprises an optical cavity CO in which the sample is arranged. This cavity CO is resonant for the incident laser beam FL so that, by its arrangement and structure, the optical cavity CO is adapted so that the incident laser beam FL performs a plurality of reflections in the optical cavity as it passes through the region R by increasing the intensity of the beam FL in the region R. This increase in intensity makes it possible to increase the intensity of the evanescent field EV and thus generate a number of distinct energy peaks in the output beam FS greater than the number of distinct energy peaks that would be obtained without the presence of said optical cavity. As explained above, detecting a larger number of distinct peaks in the output beam spectrum improves the accuracy in determining the scale factor S and offset O by selecting a number of inter-peak intervals m in step E.

Preferentially, the cavity CO is a micrometric cavity to improve the compactness of the system 1. Even more preferentially, the transport assembly SO comprises an optical fiber adapted to couple the beam FL to the cavity CO.

FIG. 7 schematically shows the method of the second embodiment of the invention. In this second embodiment, the processor UT determines that the non-linearities experienced by the charged particles as they travel and are detected are not weak or zero. For example, the processor determines that the values c×S+O are less than or equal to ten times the values NL(c). Furthermore, in step E, the processor UT determines the energy variation ΔE of a number N>2 of distinct energy peaks each numbered by an index i∈[1; N] via the first equation. This results in the following second system (S2):

$$\{ Δ E ( {c}_{i} ) = {c}_{i} \times S + O + NL ( {c}_{i} ) = \pm {p}_{i} \times {E}_{2} ; i ∈ [ 1 ; N ] \qquad ( S 2 )$$

With cᵢ the channel of the matrix detector where the distinct energy peak of index i is detected and with pi the number of photons absorbed/emitted by the charged particles of the peak of index i.

In the second embodiment, step F involves solving the second equation system (S2) to determine the values of NL(cᵢ), i∈[1; N] and the value of the scale factor S and the offset value O. In addition, step F comprises a second sub-step consisting in extrapolating the NL function from the N values NL(cᵢ), i ∈[1; N] to characterize the non-linearities undergone by the charged particles during their path and detection. Following step F, and given a number N of distinct peaks of sufficiently high energies detected, the method of the invention enables characterization of the non-linearities undergone by the charged particles as they travel through the system 1.

Preferentially, the method of the second embodiment of the invention comprises a step subsequent to step F consisting in iteratively minimizing the values of the NL function by repeating steps A to F a plurality of times and modifying parameters of the path and detection of charged particles between each iteration. In this way, the method minimizes the non-linear effects experienced by charged particles in the system 1.

For example, these parameters could be the alignment of the optical components of the system 1.

Alternatively, minimization of the NL function values is performed using the processor UT by implementing the following sub-steps:
A. generating a correction table for the pixel energy values of the matrix detector of the spectrometer SM;
B. correcting a subsequent measurement of the spectrum of a charged particle beam by the spectrometer SM using the correction table, so as to obtain energy measurements that are not or only slightly modified by non-linear effects.

1-14. (canceled)

15. A method of calibrating a spectrometer for charged particles comprising the following steps:
A. generating a monochromatic incident charged particle beam having a first energy E₁;
B. generating an incident laser beam having a second energy E₂;
C. illuminating a surface of a sample with the incident laser beam to generate an evanescent electromagnetic field in a region in the vicinity of said surface;
D. spatially and temporally superimposing the incident laser beam and the incident charged particle beam in said region in order to couple them via said evanescent electromagnetic field, generating a charged particle beam known as an output beam having a spectrum comprising a plurality of distinct energy peaks spectrally separated by a value equal to the second energy E₂;
E. measuring, using the spectrometer, all or part of the spectrum of the output beam, then determining a variation in energy ΔE of at least two of the distinct energy peaks with respect to the first energy E₁;
F. determining a value of the scale factor S and a value of the offset O specific to said measurement of the spectrum of the output beam by the spectrometer from the energy variations ΔE.

16. The method according to claim 15, wherein said variation in energy ΔE of each of the at least two distinct energy peaks is equal to ΔE=±p×E₂, with p a positive or zero integer equal to a number of inter-peak intervals separating said distinct energy peak from the peak of the spectrum at the first energy E₁ and wherein said variation in energy ΔE of each of the at least two distinct energy peaks is determined in step E by the spectrometer by the following relation, referred to as the first equation:
$$Δ E ( c ) = c \times S + O + NL ( c )$$
with c a channel of a matrix detector of the spectrometer where said distinct energy peak is detected, with NL(c) a function of the channel c representative of non-linearities undergone by the charged particles during their path and detection, a so-called NL function.

17. The method according to claim 16, wherein it is determined that said non-linearities undergone by the charged particles are weak or zero, and, in step E, the variation in energy ΔE of two of the distinct energy peaks, numbered by the index 1 and 2 respectively via the first equation is determined so as to obtain the following first system:
$$\{ \begin{matrix}Δ E ( {c}_{1} ) = {c}_{1} \times S + O = \pm {n}_{1} \times {E}_{2} \\ Δ E ( {c}_{2} ) = {c}_{2} \times S + O = \pm {n}_{2} \times {E}_{2}\end{matrix} \qquad ( S 1 )$$
step F consisting in solving the first equation system to determine the value of the scale factor S and the value of the offset.

18. The method according to claim 17, wherein an integer m>1 of inter-peak intervals separating said two peaks for which the variation in energy ΔE is determined is such that an error on the determination of the scale factor value is less than or equal to 1% of the second energy.

19. The method according to claim 16, wherein it is determined that the non-linearities undergone by said charged particles are not weak or zero and, in step E, the variation in energy ΔE of a number N>2 of distinct energy peaks each numbered by an index i∈[1; M] is determined via the first equation so as to obtain the following second system:
$$i ∈ [ 1 ; N ] \{ Δ E ( {c}_{i} ) = {c}_{i} \times S + O + NL ( {c}_{i} ) = \pm {n}_{i} \times {E}_{2} \qquad ( S 2 )$$
step F consisting in:
solving the second equation system to determine the value of the scale factor S and the value of the offset 0 and the N values NL(cᵢ), i∈[1; N] of the NL function;
extrapolating the NL function from the N values NL(cᵢ), i∈[1; N] to characterize the non-linearities undergone by the charged particles during their path and detection.

20. The method according to claim 19, comprising a step subsequent to step F consisting in iteratively minimizing the values of the NL function by repeating steps A to F a plurality of times and modifying parameters of the path and detection of charged particles between each iteration.

21. The method according to claim 15, wherein step D further comprises a sub-step consisting in measuring a spectrum of the incident laser beam simultaneously with the generation of the output beam, the determination of the value of the scale factor S and the value of the offset O being performed from said measurement of the spectrum of the incident laser beam.

22. A system for calibrating a spectrometer for charged particles, said system comprising:
a charged particle source adapted to generate a monochromatic incident charged particle beam having a first energy E₁;
a laser source adapted to generate an incident laser beam having a second energy E₂;
an optical and charged particle transport assembly adapted for:
illuminating a surface of a sample with the incident laser beam to generate an evanescent electromagnetic field in a region in the vicinity of said surface:
spatially and temporally superimposing the incident laser beam and the incident charged particle beam in said region in order to couple them via said evanescent electromagnetic field so as to generate a charged particle beam known as an output beam having a spectrum comprising a plurality of distinct energy peaks spectrally separated by a value equal to the second energy E₂;
said spectrometer being adapted to measure all or part of the spectrum of the output beam, said system further comprising a processor connected to the spectrometer and adapted for:
determining a variation in energy ΔE of at least two of the distinct energy peaks with respect to the first energy E₁;
determining a value of the scale factor S and a value of the offset O specific to said measurement of the spectrum of the output beam by the spectrometer from the energy variations ΔE.

23. The system according to claim 22, wherein the incident laser beam is a continuous beam or a pulsed beam with a spectral width of less than 40 meV.

24. The system according to claim 22, comprising an additional optical spectrometer adapted to measure a spectrum of the incident laser beam simultaneously with the generation of the output beam, the processor also being connected to the additional spectrometer so that the determination of the value of the scale factor S and the value of the offset O is effected from said measurement of the spectrum of the incident laser beam.

25. The system according to claim 22, wherein the laser source and transport assembly are adapted so that the incident laser beam has an intensity greater than or equal to 10⁸ W/cm² in said region.

26. The system according to claim 22, wherein the laser source and transport assembly are adapted so that the incident laser beam is polarized in a direction adapted to the geometry and the symmetry of the sample in order to locally maximize the intensity of the evanescent field in said region.

27. The system according to claim 22, wherein said transport assembly comprises an off-axis parabola adapted to focus the incident laser beam onto said surface of the sample, said parabola having an aperture through which the incident charged particle beam passes so that it co-propagates with the incident laser beam towards said region after the latter has reflected off said off-axis parabola.

28. The system according to claim 22, comprising a resonant optical cavity for the incident laser beam wherein the sample is arranged, said transport assembly and said optical cavity being further adapted so that the incident laser beam makes a plurality of reflections in the optical cavity as it passes through said region.
